(19) United States
(12) Patent Application Publication
(10) Pub. No.: US 2004/0142566 A1
(43) Pub. Date: Jul. 22, 2004

(54) Continuous bleed-and-feed process and equipment

(76) Inventors: Bernard Frey, Livermore, CA (US); Steven Gross, San Jose, CA (US); Bulent M. Basol, Manhattan Beach, CA (US); Homayoun Talieh, San Jose, CA (US)

Correspondence Address: NuTool, Inc., Legal Department, 1655 McCandless Drive, Milpitas, CA, 95035, US

(21) Appl. No.: 10/698,872

(22) Filed: Oct. 31, 2003

Related U.S. Application Data
(60) Provisional application No. 60/423,737, filed on Nov. 5, 2002.

(51) Int. Cl. H01L 21/302; H01L 21/461

(52) U.S. Cl. 438/689

(57) ABSTRACT

A method of performing continuous bleed-and-feed of process solution from and to a holding tank includes the steps of bleeding aged solution from the holding tank to a secondary container, measuring a predetermined amount of the aged solution in the secondary container, disposing the aged solution in the secondary container, filling the secondary container with the predetermined amount of a new solution from a supply tank, and feeding the predetermined amount of the new solution to the holding tank. In one aspect of the invention, the secondary container includes a secondary container tube having a sensor and the measuring step includes sensing the predetermined amount of the aged solution, and shutting a bleed valve for the holding tank in response to sensing the predetermined amount of the aged solution in the secondary container tube. Advantages of the invention include improved control of electrodeposited metal to improve device consistency and yield.

### RELATED APPLICATIONS

This application claims priority to U.S. Prov. No. 60/423,737 filed Nov. 5, 2002, incorporated herein by reference.

### FIELD

The invention is related to the field of semiconductor processing and specifically to a technique for continuous bleed-and-feed process and equipment.

### BACKGROUND

Electroplated copper is now commonly used to fabricate advanced integrated circuit interconnect structures. Control of electrodeposited copper material from wafer to wafer is very important for device yield considerations. Controlling the properties of the electrodeposited copper, on the other hand, requires tight control of the electrodeposition bath.

Standard copper plating electrolytes contain copper-containing base solution and additives that are introduced to improve the quality of the deposits. Typical electrolytes may contain Cl ions, accelerator additives, suppressor additives and sometimes leveler additives. The additives are organic materials that, in time, break down due to oxidation etc. Therefore, to establish certain degree of stability in the quality of the plated copper, it is customary to perform a bleed-and-feed operation to refresh the used bath. In a bleed-and-feed operation, a certain percent volume of the used electrolyte is removed from the supply tank and a corresponding fresh amount is put in. Bleed-and-feed is typically carried out once a day and 5-10% of the used electrolyte is bled and a corresponding amount is fed into the electrolyte tank. After a certain period of time, which depends on the usage of the electrolyte, the whole bath is discarded and a new bath is formulated.

Carrying out bleed-and-feed operations at relatively long intervals, such as once a day, is inconvenient and reduces up time of the equipment. Since replenishing a relatively large percentage (5-10%) of the electrolyte at one time may impact the process results on the wafers, plating is stopped during the bleed-and-feed operation and after the bath is replenished, the system is re-qualified for deposition before new substrates are processed. This is time-consuming.

In continuous bleed-and-feed approach a smaller percentage of the bath is replenished at smaller time intervals so that the “total replenishment” desired during a 24-hr period is reached in a gradual manner. For example, for a chemical delivery unit containing 200:1 of solution, it may be desired to bleed-and-feed 1 liter of solution, every hour, or 500 cc of solution every 30 minutes. Since the volume of the added fresh electrolyte is small, the condition of the bath is not drastically changed during this bleed-and-feed operation. Therefore, the operation can be automatically carried out as the wafers continue to plate with no negative impact on throughput.

### SUMMARY

The invention provides a technique for a continuous bleed-and-feed process. A method of performing continuous bleed-and-feed of process solution from and to a holding tank includes the steps of bleeding aged solution from the holding tank to a secondary container, measuring a predetermined amount of the aged solution in the secondary container, disposing the aged solution in the secondary container, filling the secondary container with the predetermined amount of a new solution from a supply tank, and feeding the predetermined amount of the new solution to the holding tank.

In one aspect of the invention, the secondary container includes a secondary container tube having a sensor and the step of measuring includes sensing the predetermined amount of the aged solution, and shutting a bleed valve for the holding tank in response to sensing the predetermined amount of the aged solution in the secondary container tube.

Advantages of the invention include improved control of electrodeposited metal to improve device consistency and yield.

### DRAWINGS

The invention is described in detail with reference to the drawings, in which:

FIG. 1 depicts an embodiment of the invention.

### DESCRIPTION OF THE INVENTION

The hardware design of the present invention allows to bleed-and-feed electrolyte as automatically and frequently as programmed. It also has flexibility of defining the amount of electrolyte to be bled and fed during the bleed-and-feed periods. This is accomplished by filling a section of a container with used electrolyte from the main electrolyte tank, dumping it to the waste line, then refilling the same section of a container with fresh electrolyte and feeding that into the main electrolyte tank.

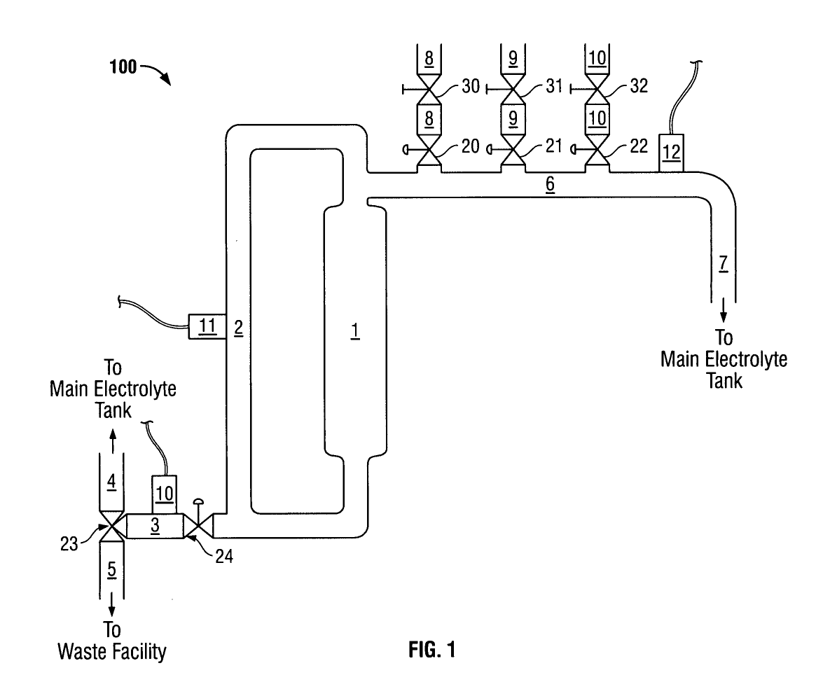

FIG. 1 shows the bleed-and-feed apparatus 100 of the present invention. Container 1 may have a total volume of 100-1000 ml depending upon the volume of the main electrolyte tank (not shown) the unit will bleed-and-feed. Tied to container 1 is a tube 2, which has a smaller volume and has a liquid sensor 11, attached to it. 3-way valve 23 can switch any electrolyte flow coming through the two-way valve 24 and the output line 3 to either the waste line 5 which leads to a waste facility (not shown) or to tank feed line 4, which leads to the main electrolyte tank.

Used electrolyte from the main electrolyte tank may come into the apparatus through two-way valve 21. Used solution needle valve 31 is used to adjust the flow of the used electrolyte through line 9 into manifold 6. Similarly, fresh electrolyte needle valve 30 adjusts the flow of the fresh electrolyte into the manifold 6 through line 8 and two-way valve 20 and the DI water needle valve 32 adjusts the flow of DI water into the manifold 6 through line 10 and two-way valve 22. All needle valves are pre-adjusted so that fluids supplied through them fill the container 1 slowly, for example in 10-60 seconds. This way, accuracy of the method is improved as will be explained later.

At the beginning of the bleed-and-feed operation all the valves are closed and the container 1 and tube 2 are empty. When the operation is initiated, preferentially by computer, valve 21 is opened and used electrolyte from the main electrolyte tank flows slowly into manifold 6 and from there into container 1 and tube 2. Liquid level rises in both container 1 and tube 2 slowly until the sensor 11 detects the liquid, at which time valve 21 is closed. Slow filling is important to assure repeatability of the volume measurement provided by the sensor 11. The height of the sensor 11 determines the volume of each bleed-and-feed step and it is adjustable. Sensor 11 position vs. volume of the bled and fed electrolyte can be easily calibrated by standard volumetric techniques.

After the valve 21 is closed, valve 24 is turned on and the 3-way valve 23 is automatically turned to the position that allows the used electrolyte in the tube 2 and container 1 to flow out to waste facility through waste line 5. Sensor 10 detects the flowing electrolyte. When the electrolyte is totally drained and the output line 3 becomes empty, signal from the sensor 10 changes and the valve 24 is closed. There may be a delay introduced between these two operations to assure complete electrolyte removal from the device. At this stage bleed function is completed and feed function can be initiated.

For feeding fresh electrolyte the valve 20 is turned on and fresh electrolyte fills up the tube 2 and container 1 just like the used electrolyte. Since the sensor 11 position is pre-set, exactly the same amount of fresh electrolyte is filled into the device as the used electrolyte that was previously bled. Then the valve 20 closes, valve 24 opens and the 3-way valve 23 is switched to the position, which directs the fresh electrolyte to the main electrolyte tank through tank feed line 4. After the feed cycle is completed all two-way valves are closed and the system is ready for the next bleed-and-feed cycle.

Certain additions, and changes may be made to the apparatus and method of the present invention without changing the core of the invention which achieves accurate bleed-and-feed process by using the same volumetric measurement device for both the bleed-and-feed cycles. Approach is simple, low-cost and very reliable since the volumetric measurement by the sensor 11 is very repeatable. Overflow line 7 in FIG. 1 is tied to the main electrolyte tank as an insurance against spills that may result from a malfunction. Valve 22 and needle valve 32 are added to bring in DI water if there is a need to rinse the device. DI water may also be used to make up any water loss in time from the main electrolyte tank. Once such water loss rate is determined an automatic DI water feed at certain intervals may be carried out by the system of FIG. 1 to assure stability of the electrolyte in the main electrolyte tank.

The process of bleed-and-feed is preferably automated and is controlled by a computer or circuit. An additive dosing approach may also be used in conjunction with bleed-and-feed. In this approach the usage of organic additives during the plating process is pre-determined and automatic dosing circuit adds to the main tank enough accelerators, suppressors and if used levelers at certain intervals. These additives break down as a function of time (idle flow) as well as during plating when charge is passed through the electrolyte. The amount of additive breakdown during plating may be different than the amount during idle flow of the electrolyte. A computer can calculate the amounts of the additives to be added into the main tank based on the total charge passed through the system for plating and total amount of electrolyte idle flow through the process modules. Then the additive amount that has been bled out during the bleed-and-feed cycle is also calculated and a corresponding amount of additive is added by the additive dosing system.

Having disclosed embodiments of the invention to satisfy the best mode requirement, variations of the invention will be apparent to those skilled in the art. This patent is intended to cover the invention and variations thereof within the spirit and scope of the claims.

1. A method of performing continuous bleed-and-feed of process solution from and to a holding tank comprising the steps:
bleeding aged solution from the holding tank to a secondary container;
measuring a predetermined amount of the aged solution in the secondary container;
disposing the aged solution in the secondary container;
filling the secondary container with the predetermined amount of a new solution from a supply tank; and
feeding the predetermined amount of the new solution to the holding tank.

2. The method of claim 1, wherein the secondary container includes a secondary container tube having a sensor and the step of measuring includes:
sensing the predetermined amount of the aged solution; and
shutting a bleed valve for the holding tank in response to sensing the predetermined amount of the aged solution in the secondary container tube.

3. The method of claim 1, wherein the secondary container is substantially smaller in volume compared to the holding tank.

4. The method of claim 1, wherein the step of bleeding includes flowing the aged solution through a manifold to the secondary container.

5. The method of claim 4, wherein the step of filling the secondary container includes flowing the predetermined amount of the new solution through the manifold to the secondary container.

6. The method of claim 1, where the step of filling the secondary container includes sensing the predetermined amount of the new solution in the secondary container.

7. The method of claim 1, wherein the step of feeding the predetermined amount of the new solution to the holding tank includes flowing the new solution in the secondary container through an output line feeding the holding tank.

8. The method of claim 2 further comprising the step of overflowing solution in the secondary container to the holding tank in response to a failure in the step of sensing.

9. The method of claim 1 further comprising the step of dosing at least one additive into the holding tank corresponding to a volume fraction of the amount of the new solution fed to the holding tank.

10. The method of claim 9, wherein the step of dosing is performed at a predetermined interval.

11. The method of claim 9, wherein the additive comprises an organic additive.

12. The method of claim 1 further comprising the step of replenishing DI water to the holding tank.

13. The method of claim 12, wherein the step of replenishing is performed at a predetermined interval.

14. The method of claim 13, wherein the step of replenishing includes:
flowing DI solution through a manifold to the secondary container;
sensing a predetermined amount of the DI water in the secondary container; and
feeding the DI water to the holding tank.
